(19) United States
(12) Patent Application Publication
(10) Pub. No.: US 2007/0105356 A1
(43) Pub. Date: May 10, 2007

(54) Method of controlling nanowire growth and device with controlled-growth nanowire

(76) Inventors: Wei Wu, Mountain View, CA (US); Theodore I. Kamins, Palo Alto, CA (US); Shashank Sharma, Sunnyvale, CA (US); R. Stanley Williams, Portola Valley, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/272,347

(22) Filed: Nov. 10, 2005

(51) Int. Cl. H01L 21/20; H01L 21/44; C30B 11/00

(52) U.S. Cl. 438/584; 438/607; 438/674; 438/490; 438/488

(57) ABSTRACT

Nanowire growth in situ on a planar surface, which is one of a crystalline surface having any crystal orientation, a polycrystalline surface and a non-crystalline surface, is controlled by guiding catalyzed growth of the nanowire from the planar surface in a nano-throughhole of a patterned layer formed on the planar surface, such that the nanowire grows in situ perpendicular to the planar surface. An electronic device includes first and second regions of electronic circuitry vertically spaced by the patterned layer. The nano-throughhole of the patterned layer extends perpendicularly between the regions. The first region has the planar surface. The device further includes a nanowire extending perpendicular from a catalyst location on the planar surface of the first region in the nano-throughhole. The nanowire forms a component of a nano-scale circuit that connects the regions.

### STATEMENT REGARDING FEDERALLY SPONSORED RESEARCH OR DEVELOPMENT

The U.S. Government has a paid-up license in this invention and the right in limited circumstances to require the patent owner to license others on reasonable terms as provided for by the terms of Contract No. MDA972-01-3-0005 awarded by the Defense Advanced Research Projects Agency.

### CROSS-REFERENCE TO RELATED APPLICATIONS

N/A

### BACKGROUND

1. Technical Field

The invention relates to nano-scale semiconductor devices and fabrication methods therefor using nanowires. In particular, the invention relates to control of fabrication of nanowires and their use in semiconductor devices.

2. Description of Related Art

A consistent trend in semiconductor technology since its inception is toward smaller and smaller device dimensions and higher and higher device densities. As a result, an area of semiconductor technology that recently has seen explosive growth and generated considerable interest is nanotechnology. Nanotechnology is concerned with the fabrication and application of so-called nano-scale structures, structures having at least one linear dimension between 1 nm and 200 nm. Such nano-scale structures have dimensions that are often as much as 50 to 100 times smaller than conventional semiconductor structures. Among the most promising of the nano-scale structures are nanowires.

Nanowires are individual low dimensional, nano-scale, crystalline structures typically characterized as having two quantum confined dimensions or directions along with one unconfined dimension or direction. The presence of the unconfined dimension in nanowires facilitates electrical conduction along that dimension. As such, nanowires may be used in applications requiring true electrical conduction instead of other forms of electron transport such as tunneling. Moreover, the confined and/or unconfined directions provide a specific density of electronic states that may impart significantly different electrical, optical and magnetic properties to nanowires as well as structures composed thereof when compared to similar structures comprising more conventional bulk crystalline materials. As such, nanowires, especially those comprising semiconductor materials, offer intriguing possibilities for use in electronic devices.

Nanowires may be fabricated by a number of different techniques. For example, nanowires may be fabricated essentially simultaneously in relatively large quantities and then ‘harvested’ or otherwise collected together as detached or free nanowires. These free nanowires may be used to connect between spaced structures or layers by separately attaching each end of the nanowire to a respective structure or layer. In other uses, the free nanowires may be deposited on a substrate in an array made up of a large number of nanowires. Such nanowire-based arrays may be employed as a circuit trace for planar interconnections in an integrated circuit or as an array of vertically-oriented nanowires that interconnect between integrated circuit layers.

In contrast to depositing detached or free nanowires on a substrate to form a useful structure, nanowires can be grown in the location where they will be used to form a portion of the structure. Semiconductor nanowires have been grown perpendicular to (111) planar surfaces of semiconductor structures using metal-catalyzed growth, wherein the semiconductor structure has an exposed (111) crystal plane from which the nanowire grows. Often vertical growth from a horizontal crystalline substrate surface is desired. Nanowires can be grown vertically perpendicular to a crystal surface of a [111]-oriented substrate. However, semiconductor substrates having a [100] crystal orientation (i.e., polished to create a smooth surface perpendicular to a [100] crystal direction) are more commonly used in the semiconductor industry. Vertical growth of nanowires from a (100) planar surface of the [100]-oriented semiconductor has not been shown to be reproducible or practical. Moreover, vertical growth of nanowires from the (111) planar surfaces has some problems with controlling one or more of location, diameter and direction and extent of nanowire growth. On a nano-scale level, any one of these growth control problems could have profound effect on the resulting semiconductor structure being fabricated using such nanowires.

Accordingly, it would be desirable to vertically grow and interconnect nanowires on semiconductor structures in a controlled fashion using commercial-oriented fabrication techniques. Such controlled growth of nanowires and the devices that incorporate them would solve a long-standing need in the area of nanotechnology.

### BRIEF SUMMARY

In some embodiments of the present invention, a method of controlling nanowire growth in situ on a substrate is provided. The method comprises guiding catalyzed growth of a nanowire from a planar surface in a nano-throughhole of a patterned layer formed on the planar surface, such that the nanowire grows in situ perpendicular to the planar surface. The planar surface is one of crystalline having any crystal orientation, polycrystalline and non-crystalline.

In other embodiments of the present invention, a method of controlling an in situ connection between vertically spaced regions of an electronic device is provided. The method comprises forming a first region of electronic circuitry. The first region has a planar surface that is one of crystalline having any crystal orientation, polycrystalline and non-crystalline. The method further comprises creating a patterned layer on the planar surface. The patterned layer has a nano-throughhole to expose a portion of the planar surface. The nano-throughhole is perpendicular to the planar surface. The method further comprises in situ growing a nanowire in the nano-throughhole from and perpendicular to the planar surface portion of the first region using catalyzed growth. The grown nanowire extends in the patterned layer such that the grown nanowire provides a contact area vertically spaced from the first region.

In other embodiments of the present invention, an electronic device having nano-scale circuitry is provided. The electronic device comprises electronic circuitry that comprises a first region and a second region vertically spaced from the first region. The first region has a planar surface that is one of crystalline having any crystal orientation, polycrystalline and non-crystalline. The electronic device further comprises a patterned layer on the planar surface of the first region between the first region and the second region. The patterned layer has a nano-throughhole perpendicular to the planar surface. The nano-throughhole extends between the first region and the second region. The electronic device further comprises a nanowire extending perpendicular from a catalyst location on the planar surface of the first region in the nano-throughhole. The nanowire forms a component of a nano-scale circuit that connects the first region to the second region.

Certain embodiments of the present invention have other features one or both of in addition to and in lieu of the features described hereinabove. These and other features of the invention are detailed below with reference to the following drawings.

### BRIEF DESCRIPTION OF THE DRAWINGS

The various features of embodiments of the present invention may be more readily understood with reference to the following detailed description taken in conjunction with the accompanying drawings, where like reference numerals designate like structural elements, and in which:

FIG. 1 illustrates a flow chart of a method of controlling nanowire growth in situ on a surface according to an embodiment or the present invention.

FIGS. 2A-2I illustrate side views of a portion of a device during fabrication that includes in situ controlled-growth nanowires according to an embodiment of the present invention.

FIG. 3 illustrates a side view of an electronic device with a controlled-growth nanowire according to an embodiment of the present invention.

### DETAILED DESCRIPTION

The embodiments of the present invention facilitate control over one or both of direction and location of nanowires grown using catalyzed growth from planar surfaces of a variety of substrates having one or more of crystalline regions having any crystal orientation, polycrystalline regions and non-crystalline regions. Some embodiments may facilitate control over uniformity of such nanowires including controlling one or both of uniform shape and uniform size. Semiconductor nanowires have been successfully grown from and perpendicular to (111) planar semiconductor surfaces using metal-catalyzed growth to provide an in situ interconnection in semiconductor structures between spaced apart layers (i.e., between circuit elements or components formed in or on a semiconductor structure). See, for example, co-pending U.S. patent application Ser. No. 10/982,051, filed Nov. 5, 2004, incorporated by reference herein.

While very promising, in situ vertical growth has been essentially limited to horizontal (111) planar surfaces of [111]-oriented semiconductor substrates. Moreover, such in situ vertical growth from (111) planar surfaces has shown inconsistencies in maintaining growth characteristics, such as one or more of a perpendicular direction of the growing nanowire, uniform length, a uniformly aligned or relatively linear or straight nanowire during growth, and a relatively constant or uniformly sized or shaped (e.g., cross-section) nanowire. Also, such in situ vertical growth has shown inconsistencies in controlling a location of the growing nanowire on the (111) horizontal surface.

As such, some embodiments of the present invention improve consistency of growth characteristics for nanowires grown in situ vertically from horizontal (111) planar surfaces using catalyzed growth. Moreover, some embodiments of the present invention provide consistency in growth characteristics of an in situ vertically grown nanowire from horizontal non-(111) planar surfaces using catalyzed growth. Effectively, the embodiments of the present invention provide consistent in situ catalyzed nanowire growth characteristics, including one or more of the perpendicular growth direction, the growth location, and the size and/or shape, for nanowires grown from any planar surface including a crystalline surface having any crystal orientation, a polycrystalline surface and a non-crystalline surface.

The terms ‘perpendicular’ and ‘vertical’ are used interchangeably herein with respect to nanowire growth to mean a growth direction about 90 degrees from a referenced surface plane or horizontal planar surface, unless otherwise specified herein. Moreover, for simplicity herein and not by way of limitation, the use of brackets ‘[ ]’ herein pertains to both a direction and directions ‘< >’ of a crystal lattice and the use of parenthesis ‘( )’ herein pertains to both a plane and planes ‘{ }’ of a crystal lattice, respectively, when used herein to enclose such numbers as 110 and 111, for example, and is intended to collectively follow common crystallographic nomenclature known in the art.

The nanowire may be one or more of a single crystalline, amorphous, and polycrystalline as well as combinations thereof. The nanowire may incorporate junctions and/or layers defined, at least in part, by different chemical compositions or by different concentrations of a dopant. Such junctions or layers may define parts of a nanowire structure, such as a part of a transistor (i.e., a gate, a source, a drain and a channel or a collector, an emitter and a base) or a part of a nanowire diode, for example. One skilled in the art is familiar with a wide variety of semiconducting, conducting, and insulating materials and combinations thereof that are employed to form nanowires. Moreover, one skilled in the art is familiar with dopant materials used in such materials. Essentially any such materials or material combinations may be used to grow the nanowire according to the present invention.

For example, the nanowire may comprise a semiconductor material made up of one or more constituent elements including, but not limited, to silicon (Si), gallium (Ga), arsenic (As), indium (In), nitrogen (N), phosphorus (P), germanium (Ge), selenium (Se), and carbon (C) (e.g., hollow carbon nanotube). In another example, the nanowire may comprise a conductive material including, but not limited to, gold (Au), silver (Ag), copper (Cu), manganese (Mn), iron (Fe), nickel (Ni), molybdenum (Mo), titanium (Ti), tungsten (W), zinc (Zn), tin (Sn), aluminum (Al), chromium (Cr), cadmium (Cd), and bismuth (Bi), and alloys thereof. In yet another example, the nanowire may comprise combinations of semiconducting and conducting materials (e.g., GaAs, GaAlAs, CdSe, and LnP) and/or oxides, nitrides, sulfides, and salts thererof (e.g., ZnO, ZnS, SiO, Si₃N₄, GeO, and CdCl). For the purposes of simplifying the discussion herein and not by way of limitation, examples that follow will refer to a silicon nanowire with the understanding that any of the above elements or combinations of elements may be substituted for the silicon and still be within the scope of the embodiments described herein.

The substrate that has a planar surface from which the nanowire is grown may be any type of substrate including, but not limited to, one or more of crystalline (e.g., a single crystal), amorphous or non-crystalline, and polycrystalline substrate or wafer. In addition, a substrate may include a region formed in or on the substrate. The region has a planar surface from which the nanowire is grown that is one of crystalline having any crystal orientation, polycrystalline and non-crystalline. A region may be formed on or in a substrate by known processes including, but not limited to, one or more of epitaxy, deposition, ion-implantation and diffusion, for example. Moreover, a crystalline substrate may have any crystal orientation, or be polished in any crystal direction, including, but not limited to, [111], [110], [100] and [112], for example, for the purposes of the various embodiments herein. In some embodiments, one or both of a crystalline substrate and a crystalline region of the substrate has a non-[111] crystal orientation. In other embodiments, one or both of a substrate and a region of the substrate has one or more of a (111) planar surface, a non-(111) planar surface and any planar surface.

For the purpose of the various embodiments herein, a ‘non-(111) planar surface’ includes within its scope one or more of a crystalline surface that is not a (111) surface, a polycrystalline surface and a non-crystalline surface, for example and not limitation, while ‘any planar surface’ includes within its scope a (111) planar surface and a non-(111) planar surface, as defined herein, for example and not limitation. Moreover, the substrate and the region thereof independently may be a material similar to any of those listed or described above for the nanowire including one or more of crystalline materials, such as semiconductor materials, polycrystalline materials, such as metals and ceramics, and amorphous materials, such as ceramics and glasses, for example and not by way of limitation.

For the purposes of simplifying the discussion herein and not by way of limitation, examples that follow may refer to a silicon substrate or a silicon planar surface with the understanding that any of the above elements (materials) or combinations of elements (materials) may be substituted for the silicon substrate or the silicon planar surface and still be within the scope of the embodiments described herein. Moreover, the substrate may be a multi-layered substrate, such as a silicon-on-insulator (SOI) substrate or a silicon-on-sapphire (SOS) substrate, for example and not limitation.

In some embodiments, the substrate is an integrated circuit (IC) substrate or wafer, such as silicon or GaAs, for example, that has formed therein or thereon regions of conventional electronic circuitry of an IC, such as a metal oxide semiconductor (MOS) IC and a complementary metal oxide semiconductor (CMOS) IC, for example and not limitation. In some embodiments, the substrate has regions of nano-electronic circuitry formed therein or thereon, such as a molecular circuit, for example and not limitation. In some embodiments, the substrate is an inexpensive glass (i.e., non-crystalline or amorphous) substrate on which circuit elements, such as thin-film transistors and interconnections, are formed. In some of any of these embodiments, the planar surface of the substrate or region of the substrate comprises an accessible or exposed circuit or circuit element to which an interconnection is to be made with a nanowire.

Nanowires may be ‘grown’ using methods such as, but not limited to, vapor-liquid-solid (VLS), vapor-solid-solid (VSS), and solution-liquid-solid (SLS) methods. For the purposes of the various embodiments described and claimed herein, nanowire growth is directed to ‘catalyzed growth’, wherein any uncatalyzed growth is relatively low by comparison (i.e., an uncatalyzed growth rate is relatively low compared to a catalyzed growth rate). Catalyzed growth is defined herein as in situ growth of a nanowire in essentially or predominantly one dimension or direction using a catalyst particle. The catalyst particle is initially located on a surface. During catalyzed growth, the nanowire grows between the surface and the catalyst particle from a location where the catalyst particle was initially located (i.e., ‘a catalyst location’). The catalyst particle comprises a catalyst material that is one or both of a metal and a nonmetal. In some embodiments, catalyzed growth may be referred to herein as ‘metal-catalyzed growth’. Examples of catalyst materials and embodiments of catalyzed growth are described in more detail below. It should be understood that a variety of in situ catalyzed growth techniques that meet the above definition may be used and still be within the scope of the embodiments described herein.

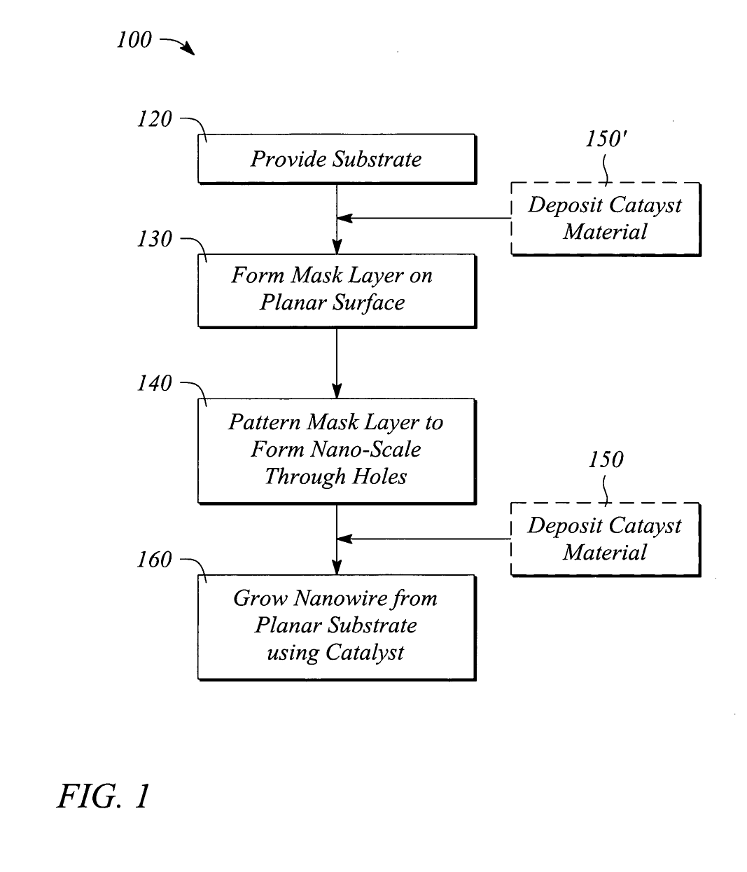

FIG. 1 illustrates a flow chart of a method 100 of controlling in situ growth of a nanowire from a planar surface according to an embodiment of the present invention. The method 100 of controlling comprises providing 120 a substrate having a planar surface. The substrate and independently, the planar surface, may be one or more of crystalline having any crystal orientation, polycrystalline and non-crystalline, as described above. In some embodiments, the planar surface may be one of a (111) planar surface, a non-(111) planar surface or any planar surface, as defined herein. Any of the above-described materials or substrates may be used for the substrate and the planar surface thereof in the method 100.

The method 100 of controlling further comprises forming 130 a mask layer on the planar surface. Depending on the embodiment, the mask layer may be an insulating material, such as an oxide or nitride of a metal or a semiconductor material, a semiconductive material or a conductive material, such as any of those described above, for example and not limitation. In some embodiments, the mask layer will remain with the substrate after nanowire growth is complete. In other embodiments, the mask layer may be sacrificial and removable at some point after nanowire growth. In either of the embodiments, the mask layer material will be compatible with the nanowire growth method used, such that the mask layer remains substantially intact during in situ growth. Moreover, a choice of mask material may depend on one or more of whether the mask layer will remain and its compatibility with the ultimate structure or device being formed using a nanowire.

The mask layer is formed 130 on the planar surface using any deposition or growth method known in the art and depends in part on the material chosen for the mask layer. For example, a silicon dioxide or a silicon nitride mask layer may be deposited or grown using one or more of chemical vapor deposition (CVD) and plasma enhanced CVD (PECVD), for example and not by way of limitation. In some embodiments, the mask layer may be planarized to facilitate a uniform surface using one or more of chemical etching, mechanical polishing and chemical mechanical planarization (CMP), for example.

The method 100 of controlling further comprises patterning 140 the mask layer to define a nano-scale sized opening through the mask layer perpendicular to the underlying planar surface of the substrate. Hereinafter, the nano-scale sized opening may be referred to interchangeably as ‘nano-pore’ ‘nano-throughhole’ or simply ‘nano-hole’. The nano-throughhole has a length defined by a thickness of the patterned mask layer where the nano-throughhole is located. In some embodiments, the nano-throughhole has a constant or uniform width and depth or diameter, depending on the cross-sectional shape of the defined nano-throughhole. Achieving a constant cross-section along the length of the nano-throughhole will depend in part on the method chosen for patterning 140 the mask layer.

In some embodiments, patterning 140 comprises coating the exposed planar surface of the formed 130 mask layer with a resist material that is relatively resilient compared to the mask material. For example, a resist material, such as a thermoplastic polymer or a UV-curable monomer, may be used. In these embodiments, patterning 140 further comprises defining a nano-pore pattern in the resist material using any of a variety of methods known in the art. In some embodiments, the nano-pore pattern is defined in the resist using nano-imprinting with a nano-imprint mold. Nano-imprinting lithography using nano-imprint molds are described in U.S. Pat. Nos. 5,772,905; 6,309,580; 6,294,450; and 6,407,443 and co-pending U.S. patent application Ser. No. 10/826,056, filed Apr. 16, 2004 and Ser. No. 10/943,559, filed Sep. 17, 2004, all of which are incorporated herein by reference.

For example, a pattern of nano-scale protrusions representative of and equivalent to a nano-pore pattern may be formed in a nano-imprint mold using any of the techniques described in the references cited hereinabove. The nano-imprint mold is contacted with and pressed into the resist layer and then removed. The nano-protrusion pattern of depressions remains in the resist after the nano-imprint mold is removed. The nano-protrusion pattern of depressions is the nano-pore pattern that comprises one or more depressions in the resist that are located equivalent to one or more locations in the underlying mask layer where a nano-throughhole is to be ultimately defined. Use of nano-imprinting lithography in this embodiment provides a parallel process of forming the nano-pores in the resist layer and is amenable to volume production applications. In other embodiments, electron beam lithography may be used to define the nano-pore pattern in the resist layer. Use of electron beam lithography provides a serial process of forming the nano-pores which is amenable to select, low-volume production applications relative to nano-imprinting lithography.

Patterning 140 further comprises directionally etching through the nano-pore depression pattern in the resist layer to form a nano-throughhole pattern in the mask layer. In some embodiments, a dry etching technique including, but not limited to, reactive ion etching, may be used to directionally etch the mask layer through the nano-pore depression pattern. The directional etching will etch the mask layer essentially vertically relative to the planar surface of the mask layer (i.e., through a thickness thereof). A nano-throughhole essentially delineates an exposed small (e.g., nano-scale size) portion or area of an underlying layer or surface. The mask layer, once patterned 140, is also referred to herein as the patterned layer.

The method 100 of controlling further comprises depositing 150 a catalyst material on the planar surface. In some embodiments, the catalyst material is deposited 150 into the nano-throughholes to the exposed portion of the planar surface. In other embodiments, the catalyst material is deposited 150′ on the planar surface before the mask layer is formed 130 and patterned 140, such that a catalyst layer is disposed between the planar surface of the substrate and the mask layer. In these embodiments, etching of the mask layer forms nano-throughholes that expose a small portion of the catalyst material on the planar surface. FIG. 1 illustrates block 150 and block 150′ with a dashed line to emphasize the different embodiments of when depositing catalyst material may occur.

The catalyst material is a material that facilitates growth of a nanowire. Hereinafter, the catalyst material may be referred to as ‘nanoparticle catalyst’ and ‘catalyst particle’ interchangeably for purposes of simplicity herein and not by way of limitation unless specifically identified otherwise. The catalyst material may include, but is not limited to, gold (Au), nickel (Ni), titanium (Ti), iron (Fe), cobalt (Co), and gallium (Ga), and respective alloys thereof. Other catalyst materials may include, but are not limited to, nonmetals, such as SiOₓ, where x ranges from about 1 to less than 2, for example. The catalyst materials used for growing a Si nanowire, for example, include, but are not limited to, Ti, Au, TiSi₂ alloy and Au—Si alloy.

The catalyst material is deposited 150, 150′ on the planar surface of the substrate using a deposition technique including, but not limited to, one or more of physical vapor deposition and chemical vapor deposition. Thermal evaporation, electron-beam evaporation and sputtering are physical vapor deposition techniques, for example. In the embodiments where the catalyst is deposited 150 in the nano-throughholes of the patterned layer, the catalyst material may be deposited 150 directionally in the nano-throughholes to the exposed planar surface. Directional deposition 150 reduces an amount of the catalyst material that may deposit 150 on the vertical walls of the nano-throughholes. Any catalyst material that does deposit 150 on the vertical walls of the nano-throughholes may be removed by thermal diffusion, which can transfer the excess catalyst material to the exposed substrate surface at the bottom of the nano-throughhole. Since the exposed planar surface of the substrate is a lower energy location for the catalyst material than the patterned layer vertical walls, then a net transfer of the catalyst material may be achievable. Moreover, any remaining catalyst on the vertical walls of the nano-throughhole may be below a threshold or target catalyst density for nanowire nucleation and growth.

In either embodiment of depositing 150, 150′, exposed portions of catalyst on the planar surface in the nano-throughhole are ultimately formed. In some embodiments, the catalyst material is deposited 150, 150′ to an average thickness ranging from about 0.01 nanometers (nm) to about 100 nm. At a thickness around the lower range of about 0.01 nm, the deposited catalyst material may form a discontinuous layer and the thicknesses averaged over an entire surface may be about 0.01 nm, while the layer may be locally thicker. In some embodiments, the catalyst material is deposited 150, 150′ to a thickness ranging from about 0.1 nm to about 5 nm. For example, see co-pending U.S. patent application Ser. No. 10/281,678, filed Oct. 28, 2002, incorporated by reference herein, for methods of forming catalyst nanoparticles.

In some embodiments where the catalyst material is deposited 150 into the nano-throughholes, depositing 150 the catalyst material is followed by removing the resist layer and any excess catalyst material from the surface of the resist layer. In other embodiments thereof, the resist layer is removed prior to depositing 150 the catalyst material. One or both of a lift-off technique and selective etching may be used to remove the resist layer and any excess catalyst material thereon from the patterned layer while leaving the patterned layer and the deposited catalyst in the nano-throughhole on the substrate surface. In the embodiments where the catalyst material is deposited 150′ on the substrate surface before forming 130 and patterning 140 the mask layer, the resist layer is removed after patterning 140.

Following deposition 150, 150′ of the catalyst material, the catalyst material is optionally annealed. In some embodiments, annealing the catalyst material will activate the catalyst particle. In other embodiments, the catalyst particle is deposited 150, 150′ in an active state and annealing is considered optional. In some embodiments, annealing is performed in a controlled environment. A controlled environment includes, but is not limited to, a reactor chamber of a material deposition system where at least temperature and pressure are selectively controlled. For example, a titanium (Ti) catalyst material may be annealed to reduce native oxide on the Ti and form the TiSi₂ alloy nanoparticle catalyst. A gold (Au) catalyst material may be annealed (e.g., activated) to form the gold-silicon alloy (Au—Si) alloy nanoparticle catalyst.

The method 100 of controlling further comprises growing 160 a nanowire from the substrate surface using the deposited 150, 150′ catalyst particle to accelerate growth. Growing 160 a nanowire comprises exposing the catalyst particle to a controlled temperature, pressure and a gas containing a material of the nanowire to be grown. For a silicon (Si) nanowire, a Si-containing gas is used, or for a germanium (Ge) nanowire, a Ge-containing gas is used, for example. For another semiconductor nanowire, the gas generally contains the precursors for the respective other semiconductor material.

In some embodiments, the catalyst particle is exposed to the gas in the reactor chamber of a material deposition system under conditions at which the uncatalyzed (i.e., normal) deposition rate is low. The catalyst accelerates the decomposition of the gas, allowing a high ratio of catalyzed-to-normal growth. As such, the temperature and pressure are regulated, and the gas or a gas mixture is introduced and controlled during nanowire growth 160. Material deposition systems including, but not limited to, chemical vapor deposition (CVD) systems, metal organic vapor phase epitaxy (MOVPE) systems, molecular beam epitaxy (MBE) systems, plasma-enhanced CVD (PECVD) systems, resistance-heated-furnace diffusion/annealing systems, and rapid thermal processing (RTP) systems may be employed for the nanowire growth 160, for example. For example, a Si nanowire may be grown 160 using a CVD system and a process that employs a Si-containing gas including, but not limited to, a gas mixture of silane (SiH₄) and hydrogen chloride (HCl), a gas of dichlorosilane (SiH₂Cl₂), or a silicon tetrachloride (SiCl₄) vapor in a hydrogen (H₂) ambient.

Nanowire growth 160 is initiated when adatoms resulting from decomposition of the particular nanowire material-containing gas diffuse through or around the catalyst particle, and the adatoms precipitate on the underlying substrate surface in the nano-throughhole. The catalyst nanoparticle may be in the liquid state or the solid state during nanowire growth. For example, the initial nanoparticle may be Au deposited on a Si substrate. The Au interacts with the substrate when the system is heated. When above the Au—Si eutectic temperature (approximately 360° C. for bulk materials, perhaps slightly lower for small nanoparticles), the resulting Au—Si nanoparticle becomes liquid. Diffusion of the nanowire-forming species through a liquid nanoparticle is rapid. When the nanoparticle is in the solid phase, diffusion is slower, narrowing the range of experimental conditions for which nanowire growth occurs.

For a Si nanowire, for example, growth 160 is initiated by diffusing silicon adatoms resulting from decomposition of the silicon-containing gas (i.e., nanowire-forming species) through or around the catalyst particle and precipitation of the silicon adatoms on the underlying substrate surface. Such precipitation on the underlying substrate forms a columnar nanowire structure (i.e., growth in essentially one dimension) with one end having one or both of a mechanical connection and an electrical connection to the underlying substrate. Moreover, growth 160 of the nanowire is continued with continued precipitation at the catalyst-nanowire interface. Such continued precipitation causes the catalyst particle to remain at a tip of a free end of the growing nanowire. For example, when using either a TiSi₂ or a Au—Si alloy nanoparticle catalyst for Si nanowire growth, an amount of the respective TiSi₂ or Au—Si alloy remains at the tip of the free end of the growing Si nanowire while the opposite end is attached to the substrate.

The nanowire grows 160 in a columnar shape from a catalyst location on the planar surface adjacent to the activated catalyst particle in the nano-throughhole. The growing nanowire assumes or mimics a direction of the nano-throughhole in the patterned layer and possibly the shape of the nano-throughhole. The catalyst particle at the tip has a similar cross-sectional dimension to that of the growing nanowire. Therefore, nano-throughholes in the patterned layer that are essentially perpendicular to the planar substrate surface will guide the nanowire growth 160 in a perpendicular or vertical direction from the planar substrate surface. This is so regardless of the type of substrate and the crystal orientation of a crystalline substrate.

The patterned layer on the substrate surface prevents a tendency of a nanowire to grow along a continuation of the [111] crystal directions of a non-[111]-oriented substrate, i.e., inclined to the substrate surface at a non-perpendicular angle. The patterned layer essentially surrounds the nanowire to avert such inclined or non-perpendicular growth tendencies and to force the nanowire to grow perpendicular to the planar substrate surface. In some embodiments, the directional change in growth may occur by way of one or both of a plastic deformation and an elastic deformation. For the plastic deformation mechanism, stress on the nanowire from the surrounding patterned layer may cause crystal defects, such as twin planes, to form and alter the orientation of the [111] growth direction with respect to the substrate. Depending on the degree of crystal defects, the electrical/electronic properties of the nanowire may be affected. For example, majority carrier properties may be only slightly affected, especially if the nanowire is heavily doped. On the other hand, minority carrier properties may be severely degraded by certain types of crystal defects, except for may be twin plane crystal defects. For the elastic deformation mechanism, the [111] growth direction may be altered by elastic bending of the nanowire. Moreover, a plastically deformed nanowire may retain its vertical direction in some embodiments where the patterned layer is subsequently removed, while an elastically deformed nanowire probably may not.

In some embodiments, the sidewall surfaces of the nano-throughhole in the patterned layer may be pre-treated to reduce or, in some embodiments, prevent, interaction of the catalyst nanoparticle with the sidewall surface of the nano-throughhole. For example, one or both of a Langmuir-Blodgett (LB) film or a self-assembled monolayer (SAM) may be deposited on the sidewall surfaces of the nano-throughhole prior to depositing 150 the catalyst nanoparticle. For example, if the catalyst nanoparticle has sufficient time (and a tendency) to interact or stick to the sidewall surface without a pre-treatment, the catalyst nanoparticle may initiate a 2-D growth on the sidewall surface, which may terminate the propagation or growth of the nanowire through the nano-throughhole. The pre-treatment may prevent such 2-D growth on the sidewall surface. In other embodiments, the masking layer may have an inherent tendency not to interact with the catalyst nanoparticle.

Moreover, the patterned layer may provide a template that shapes the growing nanowire within the nano-throughholes. For example, a nano-throughhole with an essentially circular cross-section may shape the growing 160 nanowire with a similarly circular cross-section. In other examples, the nano-throughhole and therefore, the growing 160 nanowire, may have essentially any cross-sectional shape including, but not limited to, triangular, rectangular, another polygon and oval. In some embodiments, the growing 160 nanowire may have a uniform diameter along its length as a result of growing 160 within the nano-throughhole having an essentially constant cross-sectional diameter. In other embodiments, since the uncatalyzed growth rate is low, the growing nanowire may have a constant diameter regardless of the constant cross-sectional diameter of the nano-throughhole.

In addition, the patterned layer provides a template that confines nanowire growth 160 to specific or targeted locations on the substrate surface. As such, extraneous nanowire growth in untargeted locations is reduced and in some embodiments, is essentially eliminated. The patterned layer provides control during in situ growth of one or more of nanowire direction, nanowire shape and/or uniformity, and nanowire location according to various embodiments of the present invention.

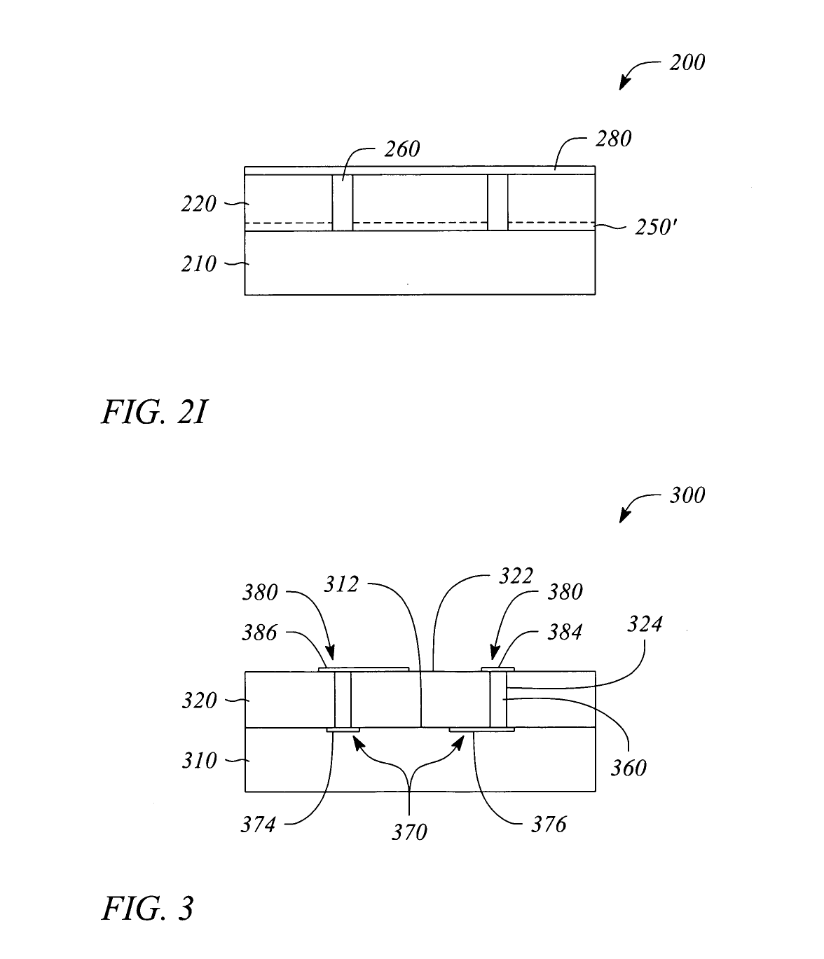

Nanowire growth 160 is continued until a target length is achieved, which depends on the ultimate use of the nanowire. In some embodiments, the target length is achieved when the free end of the nanowire is essentially coplanar with the planar surface of the patterned mask layer, such that the target length is similar to the thickness of the patterned layer. In some embodiments, the target length is less than the thickness of the patterned layer and therefore, the free end of the growing nanowire remains within the nano-throughhole. In some embodiments, the target length exceeds the thickness of the patterned layer and therefore, the growing nanowire will extend out of the nano-throughhole beyond the patterned layer for a target distance. The nanowire will maintain the essentially one dimensional growth (i.e., the same columnar shape and the same direction of growth 160) for the target distance as the growing nanowire had while growing 160 within the nano-throughhole of the patterned layer. In some embodiments, the target length is achieved when the growing nanowire contacts an opposing surface spaced from the planar surface of the underlying substrate. Upon contact, the nanowire may connect to the opposing surface in much the same way as that described in co-pending patent application Ser. No. 10/738,176, incorporated herein by reference and cited supra. The opposing surface may comprise electronic circuitry, such as one or more of micro-electronic circuitry and nano-electronic circuitry, such that the nanowire forms a connection between the electronic circuitry of the opposing surface and the electronic circuitry on the underlying substrate. An embodiment of an electronic device 300 according to the present invention that incorporates electronic circuitry is described further below with reference to FIG. 3.

Nanowire growth 160 may be halted when the nanowire has grown 160 to the target length or height. For example, the substrate or wafer may be removed from the presence of the precursor material-containing gas to halt growth 160. Alternatively, the gas flow into the chamber is stopped to cease the growth 160. As such, the nanowire 160 is controllably grown 160 in situ on the planar surface from a catalyst location, according to the various embodiments of the method 100.

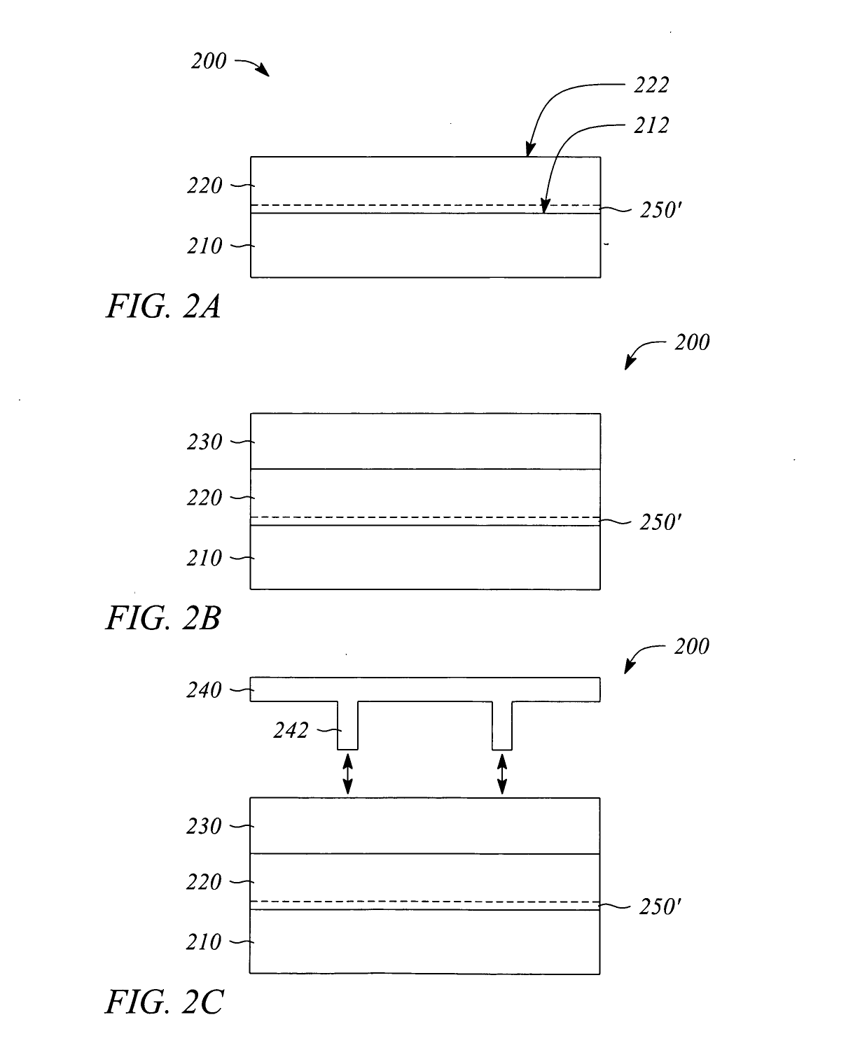

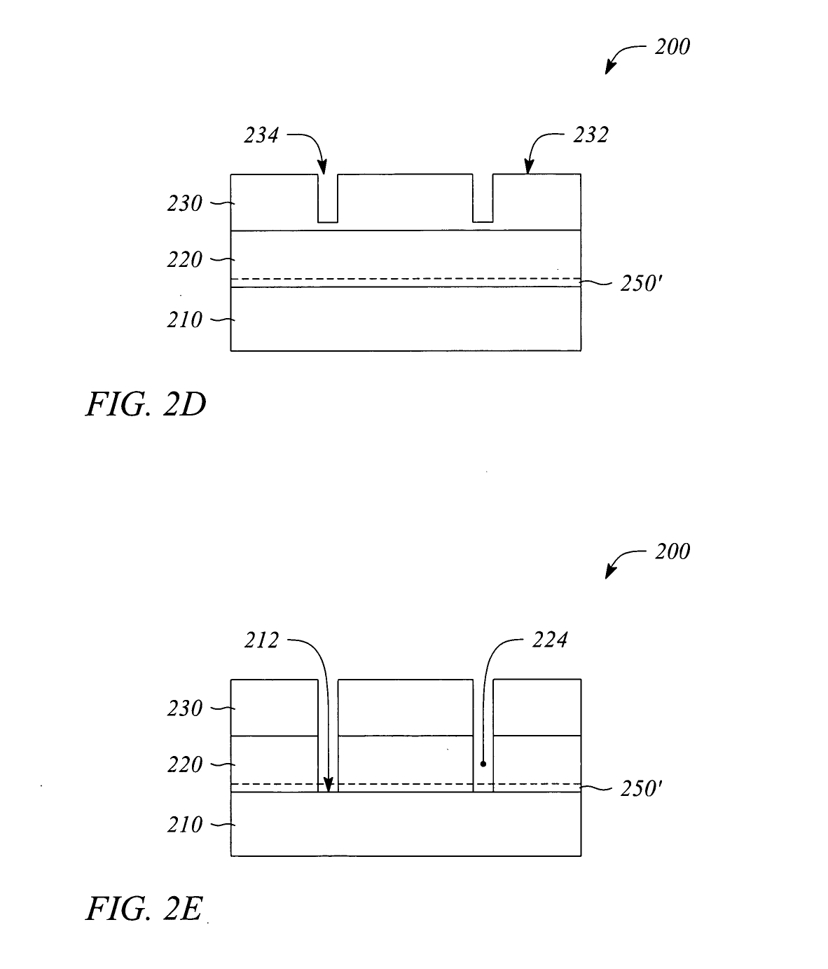

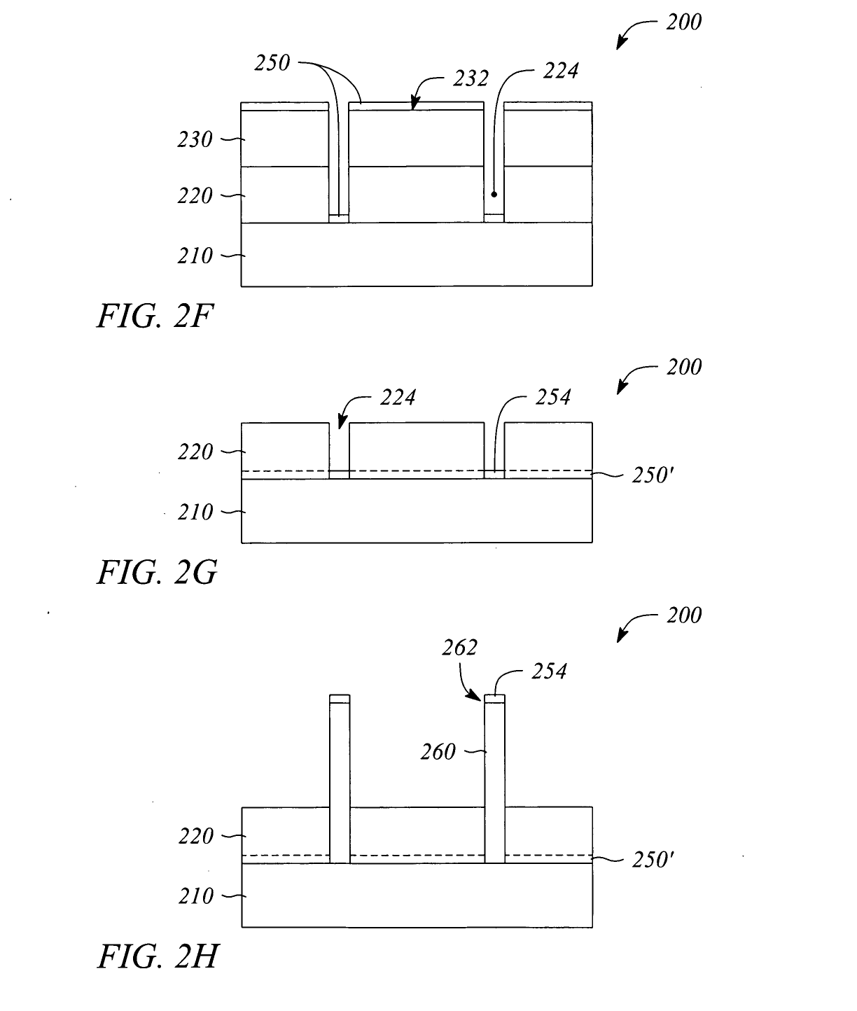

FIGS. 2A-2I illustrate side views of a portion of a device 200 during fabrication that includes in situ controlled-growth nanowires, according to an embodiment of the present invention, using the method 100 of controlling nanowire growth. In some embodiments, the method 100 of controlling nanowire growth is a method of controlling an in situ connection between vertically spaced layers of the device 200, as further described below with reference to FIG. 2I. FIG. 2A illustrates a device substrate 210 having a mask layer 220 formed on a planar surface 212 of the substrate 210. In some embodiments, the mask layer 220 is directly on or adjacent to the planar surface 212. In other embodiments, a layer of a catalyst material 250′ is deposited on the planar surface 212 of the substrate 210 prior to the masking layer 220 being formed, such that the masking layer 220 is indirectly on or adjacent to the planar surface 212. In the other embodiments, the catalyst layer 250′ is sandwiched between the substrate 210 and the masking layer 220, as illustrated by the dashed line labeled 250′ for these embodiments in FIGS. 2A-2E and 2G-2I. FIG. 2F specifically illustrates the embodiment of the catalyst material 250 deposited 150 directly on the planar surface 212. Deposition 150, 150′ of a catalyst material has been described above with reference to the method 100 of controlling nanowire growth.

The device substrate 210 and the planar surface 212 thereof are essentially as described above with respect to the method 100 of controlling nanowire growth. FIG. 2B illustrates the device substrate 210 of FIG. 2A having a resist layer 230 formed on a planar surface 222 of the mask layer 220. FIGS. 2C-2D illustrate the resist layer 230 being nano-imprinted with a nano-pore pattern using a nano-imprint mold 240 having protrusions 242 with nano-scale cross-sectional dimensions according to an embodiment of the present invention. FIG. 2E illustrates the device 200 after nano-throughholes 224 are formed through the mask layer 220 (i.e., the patterned layer 220) at the nano-pore locations in the resist layer of FIG. 2D. The nano-throughholes are formed essentially perpendicular to the planar surface 212 of the device substrate 210 and expose a small portion of either the planar surface 212 or the catalyst material 250′ in each nano-throughhole, depending on the embodiment.

In embodiments where the catalyst material 250′ is not deposited prior to forming the masking layer 220, as described above, a catalyst material 250 is deposited into the formed nano-throughholes 224 of the patterned mask layer 220 instead. FIG. 2F illustrates the catalyst material 250 deposited on the exposed planar surface 212 of the device substrate 210 in the nano-throughholes 224 of the patterned layer 220, according to some embodiments. Note that the catalyst material 250 may also deposit on a planar surface 232 of the resist layer 230. Also note that the dashed line 250′ is not included in FIG. 2F. In the embodiments where the catalyst layer 250′ is deposited on the planar surface 212 before the mask layer 220 is formed thereon, deposition of catalyst material 250 into the nano-throughholes 224 (and on the resist layer surface 232) may be omitted, such that removal of extraneous catalyst material 250 is avoided. FIG. 2G illustrates the device 200 after the resist layer 230 (and any residual catalyst material 250 thereon) is removed from the planar surface 222 of the patterned layer 220. Moreover, FIG. 2G illustrates that the catalyst material 250, 250′ in the nano-throughhole 224 is, or is annealed into, an activated nanoparticle catalyst 254.

FIG. 2H illustrates the device 200 after nanowires 260 are grown in a vertical direction from (or perpendicular to) the planar surface 212 of the device substrate 210 in the perpendicular-oriented nano-throughholes 224 of the patterned layer. In some embodiments, the nanowires 260 continue to grow out of the nano-throughholes 224. Such continued growth maintains the vertical growth direction, as illustrated in an exaggerated example in FIG. 2H. The nanoparticle catalyst 254 remains on a free end 262 of the nanowires 260 during growth.

In some embodiments, the location of the nano-throughhole 224 in the patterned mask layer 220 may correspond to a region of device 200 destined for interconnection to another region of the device 200, such as electronic circuitry regions. The in situ grown nanowire provides a connection between a first circuitry region to a second circuitry region on another layer of the device 200 which is vertically spaced from the first circuitry region. FIG. 2I illustrates the device substrate 210 with a layer 280 formed on the patterned layer 220 that interfaces with the in situ grown nanowire 260 to create a controlled in situ connection between vertically spaced layers of the device 200, according to an embodiment of the present invention. In some embodiments, when such an additional layer 280 is formed to interface with the nanowires 260, a length or height of the nanowires 260 may be controlled during in situ growth to achieve a length or height suitable for interfacing with the layer 280 formed thereon. Such nanowire height may be controlled by terminating the nanowire growth 260 process when such a suitable height is reached. In other embodiments, the nanowire 260 may be one or both of etched and polished using known etching and/or polishing techniques to achieve the height suitable for interfacing before the layer 280 is formed thereon.

FIG. 3 illustrates a side view of an electronic device 300 with a controlled-growth nanowire according to an embodiment of the present invention. The electronic device 300 comprises electronic circuitry 370 on a device substrate 310 having planar surfaces. The electronic circuitry 370 comprises one or more regions or structures described further below. The planar surface 312 of the device substrate 310 and of the electronic circuitry 370 are essentially the same as those described and defined above. For example, the device substrate 310 may be one or more of single-crystalline, polycrystalline and non-crystalline or amorphous in that the device substrate 310 may comprise regions or structures that are single-crystalline, polycrystalline or non-crystalline independently of the substrate 310. As such, the planar surface of a region may be a different material than the substrate. For example, a single-crystal silicon device substrate 310 may comprise a first region or structure therein that is a doped polycrystalline silicon and a second region or structure that is a non-crystalline oxide or an amorphous metal trace, each with a corresponding planar surface thereof. Such regions or structures may be similar to that found in CMOS devices, for example.

The electronic circuitry includes, but is not limited to, conventional electronic circuitry and nano-electronic circuitry. Conventional electronic circuitry includes, but is not limited to, metal oxide semiconductor (MOS) circuitry and complementary metal oxide semiconductor (CMOS) circuitry, for example. Nano-electronic circuitry includes, but is not limited to, traces and ground planes comprising nanowire clusters (or arrays), nanowire active devices and interconnections and molecular circuitry. See, for example, co-pending U.S. patent application Ser. No. 11/077,830, incorporated herein by reference, for nanowire cluster circuitry; and for molecular circuitry see, for example, U.S. Pat. Nos. 6,459,095; 6,559,468; 6,518,156; 6,586,965; 6,256,767; 6,128,214; 6,314,019; 6,432,740 and 6,579,742, all of which are incorporated by reference herein. In some embodiments, the substrate 310 is an integrated circuit (IC) substrate or wafer. In some embodiments, the planar surface 312 of the substrate 310 comprises a planar surface of an accessible circuit element or region 374, 376 of the electronic circuitry 370 to which an interconnection is made with a controlled-grown nanowire 360.

The electronic device 300 further comprises a mask or patterned layer 320 adjacent to the planar surface 312 of the device substrate 310. In some embodiments, the patterned layer 320 is an insulator that comprises an oxide or a nitride, such as an oxide or a nitride of silicon or aluminum, for example and not limitation. For example, the substrate may be one of a Si, a SOI, or a SOS substrate 310 that may include electronic circuitry 370 and the patterned layer 320 may be a silicon dioxide SiO₂ layer or silicon nitride Si₃N₄ layer. The patterned layer 320 covers a portion of the planar surface 312 of the substrate 310. For example, the patterned layer 320 may cover only the planar surface of regions 374, 376 of the electronic circuitry 370, or it may cover more of the planar surface 312, as illustrated in FIG. 3 by way of example. The patterned layer 320 has a set of nano-throughholes 324 extending completely through the thickness of the patterned layer 320. The set of nano-throughholes 324 is perpendicular to the planar surface 312. The set of nano-throughholes 324 is aligned to a set of areas of the planar surface 312 of the substrate 310 to which a connection is made, as described below. In some embodiments, an area of the planar surface 312 is a portion of the accessible circuit element or region 374, 376 of the electronic circuitry 370. Moreover, the accessible circuit element 374, 376 may comprise a nanoparticle catalyst material at least in the portion aligned with a nano-throughhole of the patterned layer 320.

The electronic device 300 further comprises a controlled-growth nanowire 360 within the nano-throughhole 324 of the patterned layer 320. The nanowire 360 is made of any of the materials described above for nanowires. In some embodiments, the nanowire extends perpendicular from a catalyst location (i.e., a location on the planar surface of the first region where a catalyst particle was initially located) in the nano-throughhole. In some embodiments, the nanowire 360 is grown in the nano-throughhole using any of the catalyzed growth techniques described above. In some embodiments, the nanowire 360 connects to the accessible circuitry 374, 376 on the planar surface 312 at one end and extends one of coplanar with, slightly above or beyond a planar surface 322 of the patterned layer 320, or slightly below the planar surface 322 at an opposite end to provide a contact area to the nanowire 360. In some embodiments of the electronic device 300, a contact pad is formed on the contact area of the nanowire 360 suitable for interconnection.

In some embodiments, the electronic device 300 further comprises electronic circuitry 380 on the planar surface 322 of the patterned layer 320. The electronic circuitry 380 comprises circuit elements or regions 384, 386 aligned to connect with the nanowire 360 at the planar surface 322. In some embodiments, the electronic circuitry 380 is similar in type to the electronic circuitry 370 on the substrate 310 (i.e., similarly conventional electronic or similarly nano-electronic, for example). In such embodiments, the nanowire 360 bridges between the similar circuitries 370, 380 to provide an interconnection therebetween. In other embodiments, the electronic circuitry 380 is not similar to the electronic circuitry 370 on the substrate 310 (i.e., one of the electronic circuitry 370, 380 comprises conventional circuitry and the other circuitry 370, 380 comprises nano-electronic circuitry, for example). In some embodiments, the electronic circuitry 380 comprises a nano-electronic molecular circuit, for example and not limitation. In such embodiments, the nanowire 360 bridges between the dissimilar circuitries to provide a compatible interconnection therebetween. The patterned layer 320 separates and provides electrical insulation or isolation between the electronic circuitry 370 and the electronic circuitry 380 and the nano-throughhole 324 provides a via or path in the patterned layer 320 between the circuitries 370, 380.

In some embodiments, a nano-scale circuit may be formed in the nanowire 360 during controlled nanowire growth. For example, one or more dopants known in the art may be introduced into the nanowire at different times during catalyzed growth to create junctions and other characteristics in the nanowire 360. Such junctions or characteristics in the nanowire 360 may form part of a nano-scale transistor or diode that connects with the other circuit elements of the electronic circuitry 370, 380, for example. The nanowire 360 may modulate a strength of the connection between dissimilar electronic circuitries 370, 380 or may influence an interaction between the interconnected circuitries 370, 380, for example, depending on the electronic device 300.

When a [111]-oriented substrate is used, the dominant fraction of the nanowires grow nearly perpendicular to the (111) planar surface of the substrate without controlling the catalyzed growth according to the embodiments of the present invention. However, some of the nanowires may be misoriented initially and grow uncontrolled in other directions or along (111) directions that are not perpendicular to the substrate plane. In addition to misoriented initial growth, some of the nanowires will start out growing in the nearly perpendicular direction, but will change growth direction during growth. Moreover, the nanowires will grow from locations on the substrate that may not be targeted for growth, resulting in an extra step of selectively removing the nanowires grown from undesired locations of the substrate. Furthermore, the growing nanowires may lose uniformity in shape and/or size during growth, such that some of the nanowires have curvilinear or irregular shapes along their length.

In contrast, using the method 100 of controlling nanowire growth described herein will improve one or more of the direction, consistency, location and uniformity of the catalyzed nanowire growth on the [111]-oriented substrate or wafer, as well as on non [111]-oriented substrates, including crystalline substrates having other crystal orientations, non-crystalline substrates and polycrystalline substrates, or a planar surface thereof. For example, the growth direction of misaligned nanowires may be forced into the perpendicular direction, as described above, so that all the nanowires are properly aligned. In addition, if the nanowire growth is blocked when the nanowire impinges on the mask material surrounding the nano-throughhole, the misaligned nanowires may cease growing, leaving only those nanowires which are properly aligned. In some embodiments, the ability to block or guide growth may depend on the choice of the mask material in which the nano-throughholes are formed.

Thus, there have been described embodiments of a method of controlling in situ growth of a nanowire, a method of controlling an in situ connection in a device and an electronic device having a controlled-growth nanowire incorporated therein. It should be understood that the above-described embodiments are merely illustrative of some of the many specific embodiments that represent the principles of the present invention. Clearly, those skilled in the art can readily devise numerous other arrangements without departing from the scope of the present invention as defined by the following claims.

What is claimed is:

1. A method of controlling nanowire growth in situ on a surface comprising:
guiding catalyzed growth of a nanowire from a planar surface in a nano-throughhole of a patterned layer formed on the planar surface, such that the nanowire grows in situ perpendicular to the planar surface,
wherein the planar surface is one of crystalline having any crystal orientation, polycrystalline and non-crystalline.

2. The method of controlling of claim 1, further comprising depositing a catalyst material on the planar surface, such that the catalyst material is exposed in the nano-throughhole for the catalyzed growth of the nanowire.

3. The method of controlling of claim 2, wherein the catalyst material is deposited either before the patterned layer is formed or after the nano-throughhole in patterned layer is formed.

4. The method of controlling of claim 1, wherein the planar surface is either a (111) planar surface or a non-(111) planar surface, the non-(111) planar surface being one of crystalline, polycrystalline and non-crystalline, and wherein the nano-throughhole is perpendicular to the planar surface.

5. The method of controlling of claim 1, wherein electronic circuits that are vertically separated by the patterned layer are interconnectable by the guided catalyzed nanowire growth, one of the electronic circuits comprising the planar surface.

6. A method of controlling nanowire growth in situ from a surface comprising:
forming a patterned layer on a surface of a substrate, the patterned layer having a nano-throughhole perpendicular to the surface that exposes a nano-scale portion of the surface, the exposed surface portion being one of a (111) planar surface and a non-(111) planar surface, the non-(111) planar surface being one of crystalline, polycrystalline and non-crystalline; and
in situ growing a nanowire in the nano-throughhole from the exposed surface portion perpendicular to the planar surface using catalyzed growth.

7. The method of controlling of claim 6, wherein one or both of a direction and a location of the in situ growing nanowire is controlled with the patterned layer.

8. The method of controlling of claim 6, wherein in situ growing a nanowire comprises depositing a catalyst material on the surface of the substrate, such that the catalyst material is located on the exposed surface portion, and growing the nanowire using the catalyst material.

9. The method of controlling of claim 6, further comprising depositing a catalyst material on the surface of the substrate such that the catalyst material is located on the exposed surface portion, the catalyst material facilitating in situ nanowire growth from the planar surface in the nano-throughhole, the catalyst material being deposited either before or after the patterned layer is formed.

10. The method of controlling of claim 6, wherein the patterned layer guides the in situ growing nanowire perpendicular to the planar surface regardless of whether the planar surface is crystalline having any crystal orientation, polycrystalline or non-crystalline.

11. A method of controllably growing a nanowire in situ on a planar surface comprising:
growing a nanowire in a nano-throughhole of a patterned layer from a planar surface of a substrate, the planar surface comprising a nanoparticle catalyst to facilitate nanowire growth, the patterned layer being formed on the planar surface, the nanowire growing in a direction on the planar surface defined by the nano-throughhole regardless of whether the planar surface is crystalline having any crystal orientation, polycrystalline or non-crystalline.

12. A method of controlling an in situ connection between vertically spaced regions of an electronic device comprising:
forming a first region of electronic circuitry, the first region having a planar surface that is one of crystalline having any crystal orientation, polycrystalline and non-crystalline;
creating a patterned layer on the planar surface, the patterned layer having a nano-throughhole to expose a portion of the planar surface, the nano-throughhole being perpendicular to the planar surface; and
in situ growing a nanowire in the nano-throughhole from and perpendicular to the planar surface of the first region using catalyzed growth, the grown nanowire extending in the patterned layer such that the grown nanowire provides a contact area vertically spaced from the first region.

13. The method of controlling of claim 12, further comprising:
forming a second region of electronic circuitry on the patterned layer vertically spaced from the first region that interfaces with the contact area of the grown nanowire.

14. The method of controlling of claim 12, further comprising:
forming a contact pad on the contact area of the grown nanowire to interconnect to the first region.

15. The method of controlling of claim 12, wherein creating a patterned layer comprises:
forming a mask layer on the planar surface of the first region;
coating the mask layer with a resist layer;
defining a location in the resist layer of the nano-throughhole; and
etching through the mask layer at the defined location to form the nano-throughhole that exposes the planar surface of the first region.

16. The method of controlling of claim 15, wherein defining a location in the resist layer comprises using one or both of nano-imprint lithography and electron beam lithography.

17. The method of controlling of claim 12, wherein in situ growing a nanowire comprises:
providing a nanoparticle catalyst on the exposed surface portion of the first region; and
growing the nanowire from the planar surface facilitated by the nanoparticle catalyst in the nano-throughhole, the nanowire having an end connected to the planar surface and a free end, the nanoparticle catalyst being on the free end.

18. The method of controlling of claim 17, wherein providing a nanoparticle catalyst comprises forming the nanoparticle catalyst on the planar surface of the first region, wherein forming the nanoparticle catalyst comprises one or both of depositing the nanoparticle catalyst on the planar surface of the first region before the patterned layer is created and directionally depositing the nanoparticle catalyst in the nano-throughhole of the patterned layer onto the exposed surface portion of the first region.

19. The method of controlling of claim 12, wherein the first region comprises a nanoparticle catalyst on the planar surface, the nanoparticle catalyst being exposed in the nano-throughhole, the nanoparticle catalyst facilitating the catalyzed growth of the in situ growing nanowire.

20. The method of controlling of claim 12, wherein creating a patterned layer controls one or both of a location and a direction of the in situ nanowire connection.

21. The method of controlling of claim 12, wherein the planar surface of the first region is one of a (111) planar surface and a non-(111) planar surface, the non-(111) planar surface being one of crystalline, polycrystalline and non-crystalline.

22. A method of controlling nanowire growth in situ from a substrate comprising:
creating a patterned layer on a surface of a substrate, the patterned layer having a nano-throughhole that exposes a portion of the surface, the nano-throughhole being perpendicular to the surface, the exposed surface portion being a non-(111) planar surface, the non-(111) planar surface being one of crystalline, polycrystalline and non-crystalline; and
in situ growing a nanowire in the nano-throughhole from and perpendicular to the exposed surface portion using catalyzed growth,
wherein one or both of a direction and a location of the in situ growing nanowire is controlled.

23. A method of controlling an in situ connection between vertically spaced regions of an electronic device comprising:
forming a first region of a device, the first region having a (111) planar surface;
creating a patterned layer on the planar surface, the patterned layer having a nano-throughhole to expose a portion of the planar surface, the nano-throughhole being perpendicular to the planar surface; and
in situ growing a nanowire in the nano-throughhole from and perpendicular to the planar surface portion of the first region using catalyzed growth, the grown nanowire extending in the patterned layer such that the grown nanowire provides a contact area vertically spaced from the first region,
wherein one or both of a direction and a location of the in situ nanowire connection is controlled.

24. An electronic device having nano-scale circuitry comprising:
electronic circuitry that comprises a first region and a second region vertically spaced from the first region, the first region having a planar surface that is one of crystalline having any crystal orientation, polycrystalline and non-crystalline;
a patterned layer on the planar surface of the first region between the first region and the second region, the patterned layer having a nano-throughhole perpendicular to the planar surface, the nano-throughhole extending between the first region and the second region; and
a nanowire extending perpendicular from a catalyst location on the planar surface of the first region in the nano-throughhole, the nanowire forming a component of a nano-scale circuit that connects the first region to the second region.

25. The electronic device of claim 24, wherein the planar surface of the first region is a (111) planar surface.

26. The electronic device of claim 24, wherein the planar surface of the first region is a non-(111) planar surface, the non-(111) planar surface being one of crystalline, polycrystalline and non-crystalline.

27. The electronic device of claim 24, wherein the nanowire comprises one or both of nano-scale active circuitry and nano-scale passive circuitry.

28. The electronic device of claim 24, wherein the first region and the second region of the electronic circuitry independently comprises either nano-electronic circuitry or conventional semiconductor circuitry, the nanowire connecting between the circuitries.

29. The electronic device of claim 28, wherein the nano-electronic circuitry comprises a molecular circuit.

30. The electronic device of claim 28, wherein the conventional semiconductor circuitry comprises a metal oxide semiconductor (MOS) integrated circuit.

31. An electronic device having a controlled-grown nanowire interconnection comprising:
electronic circuitry supported by a device substrate, the electronic circuitry comprising a first region having a planar surface that is either a (111) planar surface or a non-(111) planar surface, the non-(111) planar surface being one of crystalline, polycrystalline and non-crystalline, a portion of the first region comprising a catalyst material, the electronic circuitry further comprising a second region vertically spaced from the first region;
a patterned layer on the planar surface of the first region between the first region and the second region, the patterned layer having a nano-throughhole perpendicular to the planar surface, the nano-throughhole extending between the first region and the second region; and
a nanowire grown in situ in the nano-throughhole from a location of the catalyst material on and perpendicular to the planar surface of the first region, the nanowire connecting between the vertically spaced first region and second region.

32. The electronic device of claim 31, wherein the patterned layer is an insulator layer that separates the first region from the second region of the electronic circuitry, the nanowire providing a nano-scale circuit that comprises one or both of an active circuit interconnection and a passive circuit interconnection between the first region and the second region of the electronic circuitry.

33. The electronic device of claim 31, wherein one or both of a direction and a location of the nanowire interconnection is controlled by the patterned layer.
